(19) United States
(12) Patent Application Publication
(10) Pub. No.: US 2025/0349631 A1
(43) Pub. Date: Nov. 13, 2025

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Yi-Huan LIAO, Hsinchu County (TW); Ping-Yin HSIEH, Hsinchu city (TW); Chih-Hao CHEN, Taipei city (TW); Li-Hui CHENG, New Taipei city (TW)

(73) Assignee: Taiwan Semiconductor Manufacturing Company, Ltd., Hsinchu (TW)

(21) Appl. No.: 18/660,582

(22) Filed: May 10, 2024

(51) Int. Cl. H01L 23/053; H01L 23/00; H01L 25/00; H01L 25/065

(52) U.S. Cl. CPC H01L 23/053; H01L 25/0655; H01L 25/50; H01L 24/04; H01L 24/08; H01L 24/16; H01L 24/32; H01L 24/73; H01L 2224/0401; H01L 2224/08225; H01L 2224/16227; H01L 2224/32137; H01L 2224/32225; H01L 2224/73204; H01L 2924/1815

(57) ABSTRACT

A package structure is provided. The package structure includes a first package component and a second package component bonded to the first package component. The package structure includes an electronic component disposed on the second package component. The package structure includes a thermal interface material over the first package component. The package structure includes a first adhesive wall located between the first package component and the electronic component. The package structure also includes a lid structure bonded to the second package component.

### BACKGROUND

The semiconductor industry has experienced rapid growth due to ongoing improvements in the integration density of a variety of electronic components (e.g., transistors, diodes, resistors, capacitors, etc.). For the most part, improvements in integration density have resulted from iterative reductions of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

Although existing package structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1K illustrates cross-sectional views of intermediate steps during a process for fabricating a first package component in accordance with some embodiments.

FIGS. 2A through 2F illustrate cross-sectional views of various stages of a method for fabricating a package structure in accordance with some embodiments.

FIG. 3 illustrates a schematic top view of the package structure in accordance with some embodiments.

FIG. 4 illustrates a cross-sectional view of the package structure in accordance with some embodiments.

FIG. 5 illustrates a cross-sectional view of the package structure in accordance with some embodiments.

FIGS. 6A through 6G illustrate cross-sectional views of various stages of a method for fabricating the package structure in accordance with some embodiments.

FIG. 7 illustrates a schematic top view of the package structure in accordance with some embodiments.

FIGS. 8A and 8B illustrate cross-sectional views of the package structure in accordance with some embodiments.

FIG. 9 illustrates a schematic top view of the package structure in accordance with some embodiments.

FIGS. 10A and 10B illustrate cross-sectional views of the package structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and method for fabricating the same are provided. The package structure includes multiple adhesive walls as a barrier to confine the thermal interface material within a predetermined region. As a result, the voids or defects in the thermal interface material may be reduced. In addition, at least one opening is formed in the adhesive walls to relieve the pressure of the thermal interface material. Moreover, the protective material may be confined within the region defined by the first adhesive wall. Accordingly, the dimensions (such as the width and the height) of the protective material may be controlled, thereby reducing the cost of forming the protective material.

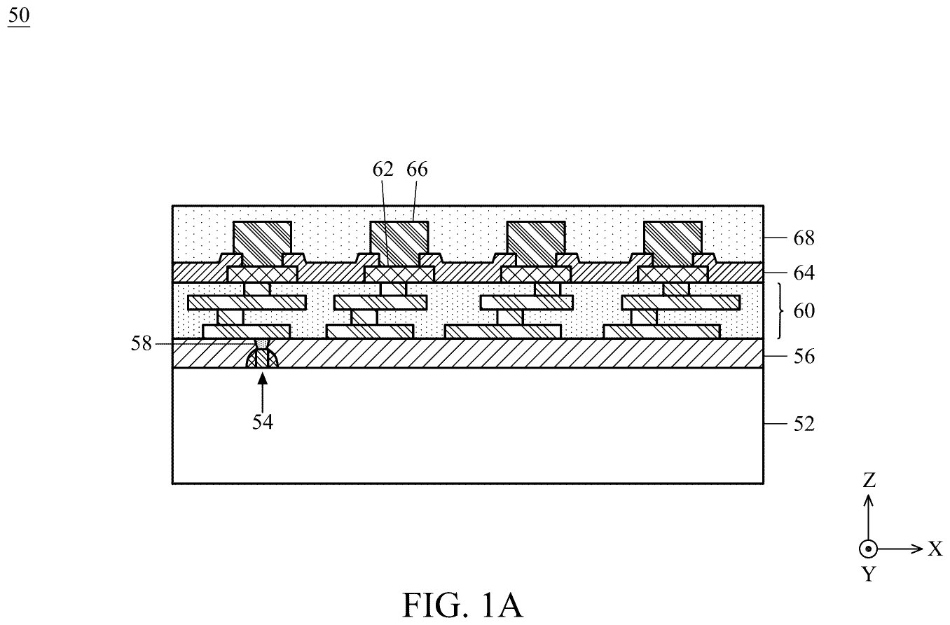

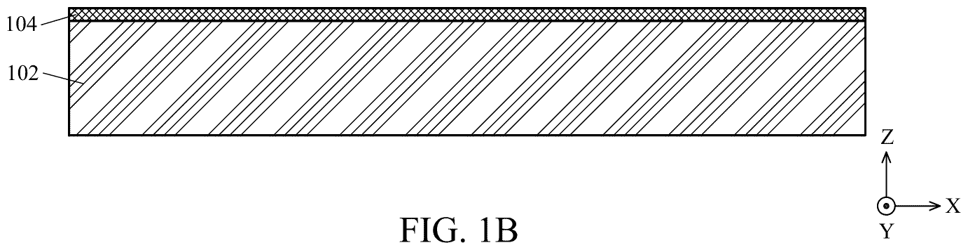

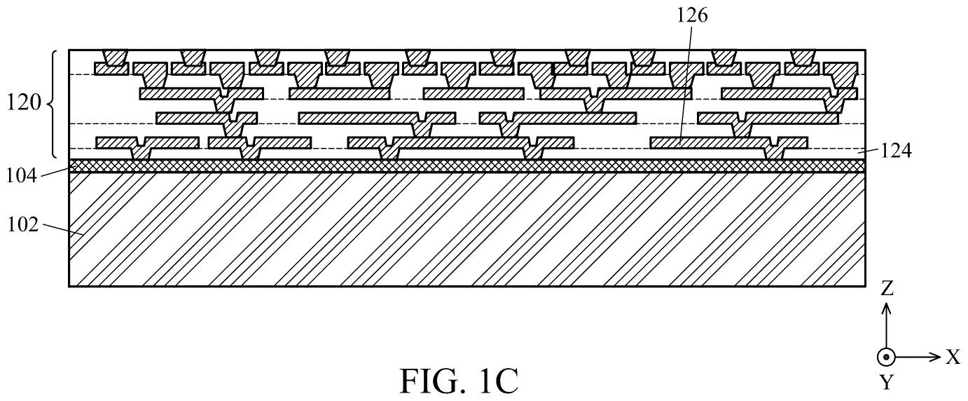

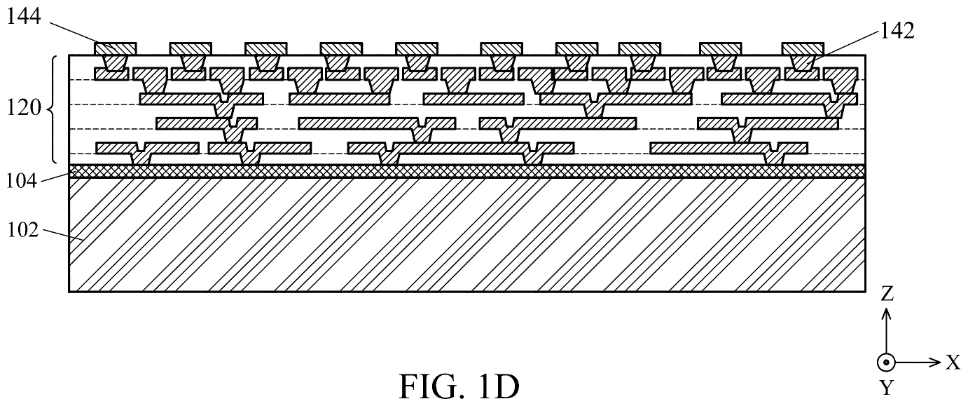

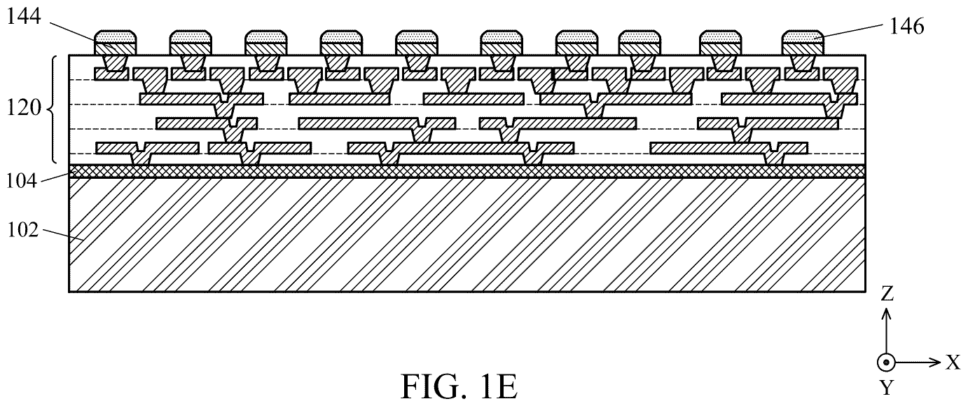

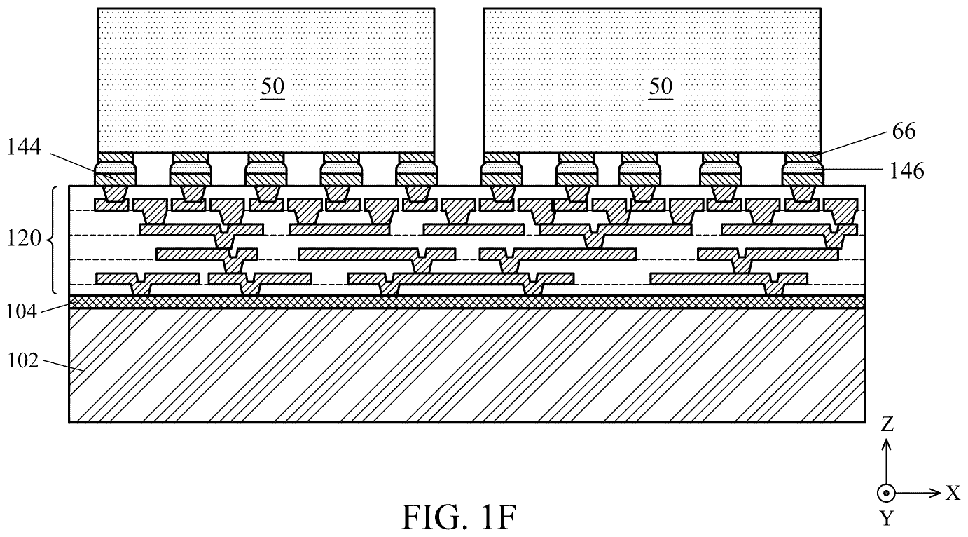

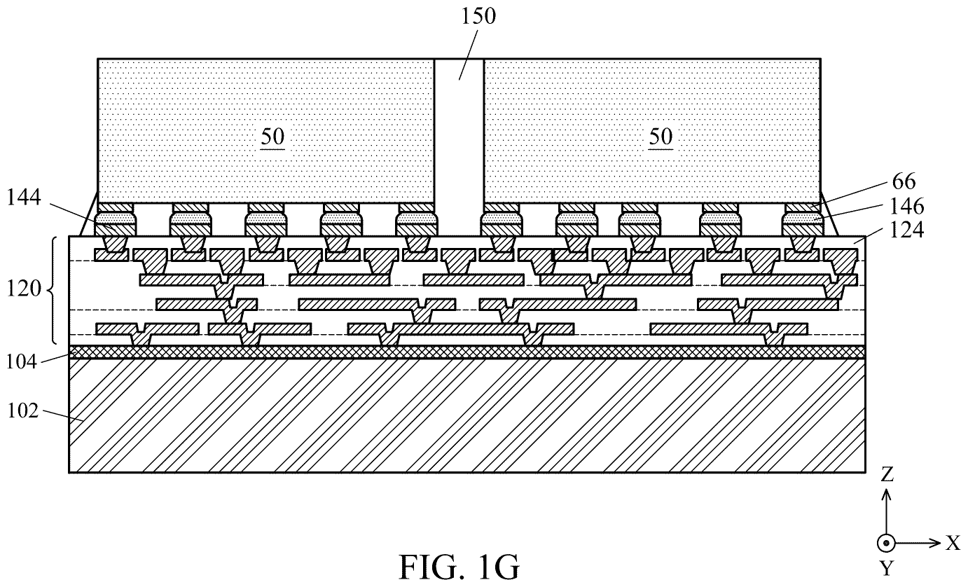

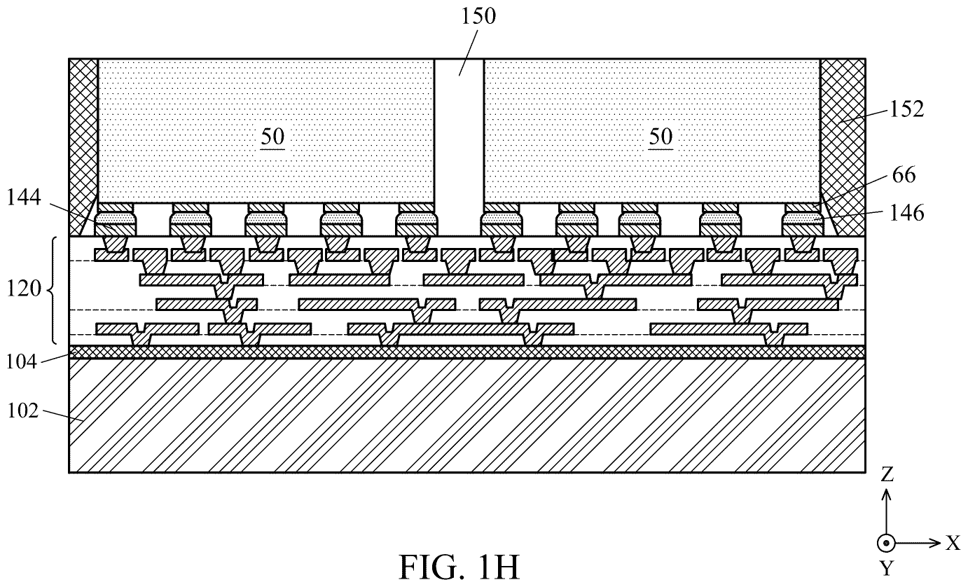

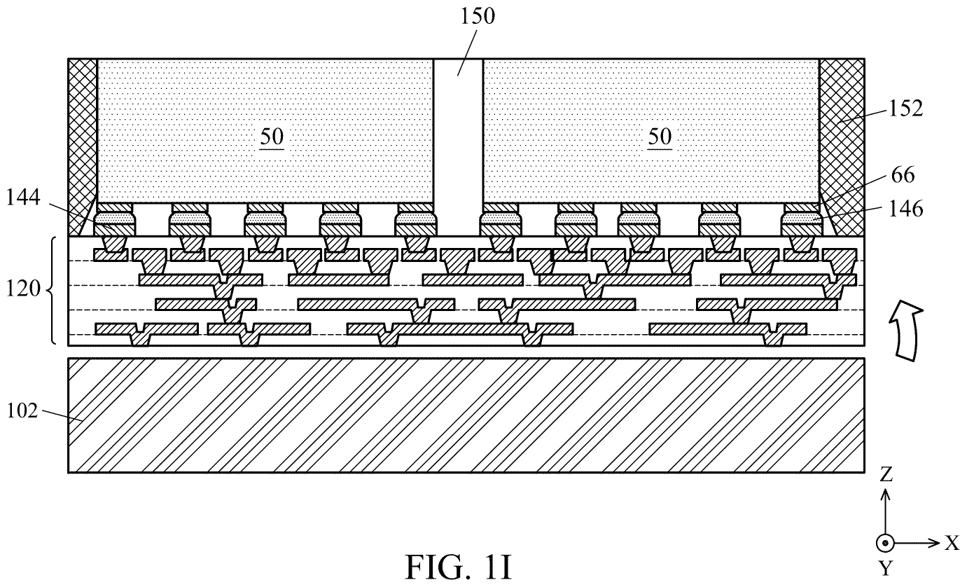

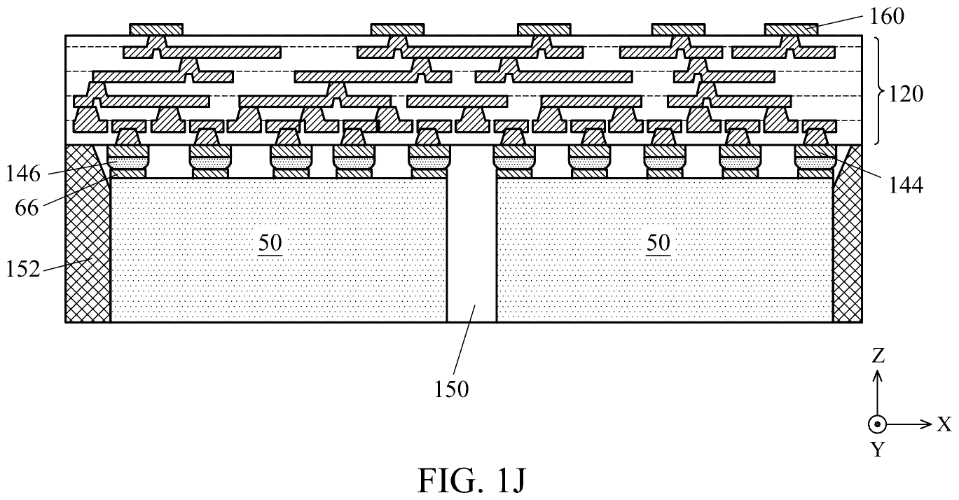

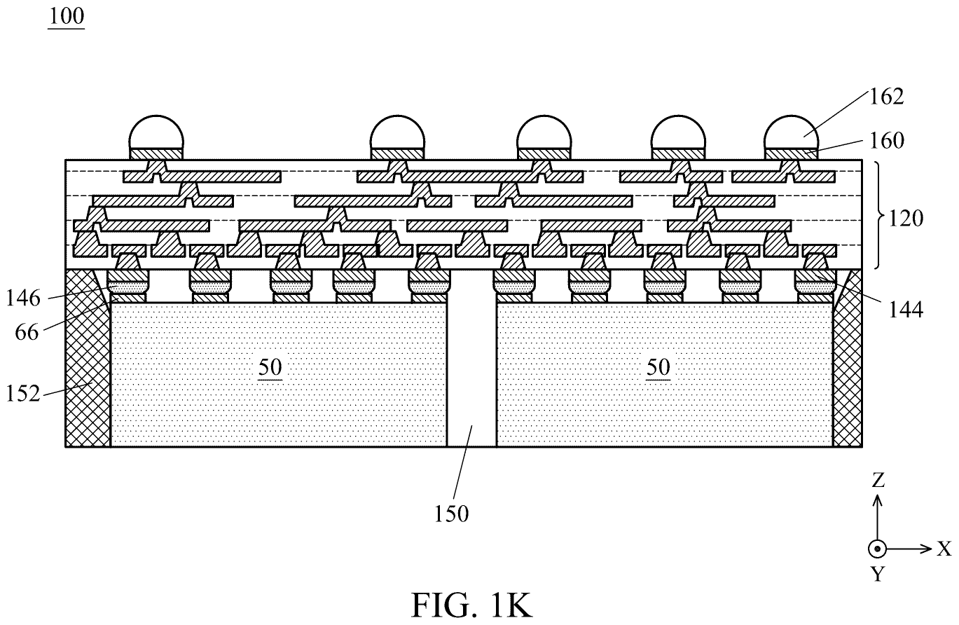

FIGS. 1A through 1K illustrates cross-sectional views of intermediate steps during a process for fabricating a first package component 100 in accordance with some embodiments. FIG. 1A illustrates a cross-sectional view of an integrated circuit die 50 in accordance with some embodiments. The integrated circuit die 50 will be packaged in subsequent processing to form an integrated circuit package. In some embodiments, the integrated circuit die 50 includes a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

In some embodiments, the integrated circuit die 50 is formed in a wafer, which may include different device regions that are singulated in subsequent steps to form a plurality of integrated circuit dies. In some embodiments, the integrated circuit die 50 is processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. In some embodiments, the semiconductor substrate 52 includes other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1A), sometimes called a front side and an inactive surface (e.g., the surface facing downwards in FIG. 1A), sometimes called a back side.

In some embodiments, devices (represented by a transistor) 54 are formed at the front side of the semiconductor substrate 52. In some embodiments, the devices 54 are active devices (e.g., transistors, diodes, etc.), capacitors, resistors, etc. An inter-layer dielectric (ILD) 56 is over the front side of the semiconductor substrate 52. In some embodiments, the ILD 56 surrounds and may cover the devices 54. In some embodiments, the ILD 56 includes one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

In some embodiments, conductive plugs 58 extend through the ILD 56 to electrically and physically couple the devices 54. For example, when the devices 54 are transistors, the conductive plugs 58 may couple the gates or source/drain regions of the transistors. In some embodiments, the conductive plugs 58 is formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. In some embodiments, the interconnect structure 60 is formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. In some embodiments, the die connectors 66 are formed by, for example, plating, or the like. The die connectors 66 electrically couple the respective integrated circuits of the integrated circuit die 50.

Optionally, solder regions (e.g., solder balls or solder bumps) may be disposed on the pads 62. In some embodiments, some solder balls are used to perform chip probe (CP) testing on the integrated circuit die 50. In some embodiments, the CP testing is performed on the integrated circuit die 50 to ascertain whether the integrated circuit die 50 is a known good die (KGD). In some embodiments, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. Initially, in some embodiments, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well.

In some embodiments, the dielectric layer 68 includes a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), or the like; the like, or a combination thereof. In some embodiments, the dielectric layer 68 is formed, for example, by spin coating, lamination, chemical vapor deposition (CVD), or the like.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure 60.

Next, as shown in FIG. 1B, multiple integrated circuit dies 50 are packaged to form an integrated circuit package. In some embodiments, the integrated circuit packages may also be referred to as integrated fan-out (InFO) packages. However, the present disclosure is not limited thereto. It should be noted that a plurality of first package components 100 may be formed in a wafer and singulated in the processes. For the sake of clarity and simplicity, one first package component 100 is shown in the present disclosure.

In some embodiments, a carrier substrate 102 is provided, and a release layer 104 is formed on the carrier substrate 102. The carrier substrate 102 may be a glass carrier substrate, a ceramic carrier substrate, or the like. In some embodiments, the carrier substrate 102 includes a wafer, such that multiple packages can be formed on the carrier substrate 102 simultaneously.

In some embodiments, the release layer 104 is formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. In some embodiments, the release layer 104 may be dispensed as a liquid and cured, may be a laminate film laminated onto the carrier substrate 102, or may be the like. In some embodiments, the top surface of the release layer 104 is leveled and has a high degree of planarity.

Then, as shown in FIG. 1C, a redistribution structure 120 is formed over the release layer 104. In some embodiments, the metallization patterns may also be referred to as redistribution layers or redistribution lines. The redistribution structure 120 is shown as an example having multiple layers of metallization patterns 126 and dielectric layers 124 that are alternatively stacked. In some embodiments, the dielectric layer 124 is formed of a photo-sensitive material such as PBO, polyimide, BCB, or the like, which may be patterned using a lithography mask. In some embodiments, the dielectric layers 124 are formed by spin coating, lamination, CVD, the like, or a combination thereof. In some embodiments, the dielectric layer 124 may be patterned by an acceptable process, such as by exposing and developing the dielectric layers 124 to light when the dielectric layers 124 are a photo-sensitive material or by etching using, for example, an anisotropic etch.

In some embodiments, the metallization patterns 126 include conductive elements extending along the major surface of the dielectric layers 124 and extending through the dielectric layers 124. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the metallization pattern 126. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

As shown in FIG. 1D, conductive vias 142 are then formed in the redistribution structure 120. As an example to form the conductive vias 142, a seed layer is formed in the openings extending through the dielectric layer 124. In some embodiments, the seed layer is a metal layer, which is a single layer or a composite layer comprising a plurality of sub-layers formed of different materials. In some embodiments, the seed layer comprises a titanium layer and a copper layer over the titanium layer. In some embodiments, the seed layer is formed using, for example, PVD or the like. A conductive material is then formed on the seed layer in the openings. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the conductive vias 142.

In some embodiments, under-bump metallurgies (UBMs) 144 are formed for external connection to the conductive vias 142. The UBMs 144 may be referred to as pads 144. The UBMs 144 have bump portions on and extending along the major surface of the dielectric layer 124 and physically and electrically couple the conductive vias 142. In some embodiments, the UBMs 144 are formed of the same material as the conductive vias 142. In some embodiments, the UBMs 144 includes alloys such as electroless nickel, electroless palladium, immersion gold, electroless nickel, or the like.

Next, as shown in FIG. 1E, conductive connectors 146 are formed on the UBMs 144. In some embodiments, the conductive connectors 146 includes ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 146 includes a conductive material such as solder, copper, aluminum, gold, nickel, silver, palladium, tin, the like, or a combination thereof. In some embodiments, the conductive connectors 146 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 146 comprise metal pillars (such as a copper pillar) formed by sputtering, printing, electro plating, electroless plating, CVD, or the like. In some embodiments, the metal pillars are solder free and have substantially vertical sidewalls. In some embodiments, a metal cap layer is formed on the top of the metal pillars. In some embodiments, the metal cap layer includes nickel, tin, tin-lead, gold, silver, palladium, indium, nickel-palladium-gold, nickel-gold, the like, or a combination thereof and may be formed by a plating process.

Then, as shown in FIG. 1F, integrated circuit dies 50 are attached to the structure of FIG. 1E. A desired type and quantity of integrated circuit dies 50 are adopted. In some embodiments, the integrated circuit dies 50 are referred to as package modules. In the embodiment shown, multiple integrated circuit dies 50 are adhered adjacent one another. For example, one of the integrated circuit dies 50 may be a logic device, such as a central processing unit (CPU), a graphics processing unit (GPU), a system-on-a-chip (SoC), a microcontroller, or the like. The other integrated circuit die 50 may be a memory device, such as a dynamic random access memory (DRAM) die, a static random access memory (SRAM) die, a hybrid memory cube (HMC) module, a high bandwidth memory (HBM) module, or the like. In some embodiments, the integrated circuit dies 50 are the same type of dies, such as SoC dies. In some embodiments, the integrated circuit dies 50 are formed in the processes of the same technology node, or they are formed in the processes of different technology nodes. For example, one of the integrated circuit dies 50 may be of a more advanced process node than the other of the integrated circuit dies 50. The integrated circuit dies 50 may be different sizes (e.g., different heights and/or surface areas), or they may be the same size (e.g., the same height and/or surface area).

In some embodiments, the integrated circuit dies 50 are attached to the conductive connectors 146. That is, the die connectors 66 of the integrated circuit dies 50 are connected to the conductive connectors 146 opposite the UBMs 144.

In some embodiments, the conductive connectors 146 are reflowed to attach the integrated circuit dies 50 to the UBMs 144. The conductive connectors 146 electrically and/or physically couple the redistribution structure 120, including metallization patterns in the redistribution structure 120, to the integrated circuit dies 50.

In some embodiments, the conductive connectors 146 have an epoxy flux (not shown) formed thereon before they are reflowed with at least some of the epoxy portion of the epoxy flux remaining after the integrated circuit dies 50 are attached to the redistribution structure 120. This remaining epoxy portion may act as an underfill to reduce stress and protect the joints resulting from reflowing the conductive connectors 146.

As shown in FIG. 1G, an underfill 150 is formed between the integrated circuit dies 50 and the dielectric layer 124, including between and around the UBMs 144, the conductive connectors 146, and the die connectors 66. In some embodiments, the underfill 150 is formed by a capillary flow process after the integrated circuit dies 50 are attached or is formed by a suitable deposition method before the integrated circuit dies 50 are attached. In some embodiments, the underfill 150 is also between the integrated circuit dies 50.

Next, as shown in FIG. 1H, an encapsulant 152 is formed around the integrated circuit dies 50, the conductive connectors 146, and the underfill 150. After formation, the encapsulant 152 encapsulates the conductive connectors 146 and the integrated circuit dies 50. In some embodiments, the encapsulant 152 is a molding compound, epoxy, or the like. In some embodiments, the encapsulant 152 is applied by compression molding, transfer molding, or the like. In some embodiments, the encapsulant 152 is applied in liquid or semi-liquid form and then subsequently cured. In some embodiments, a planarization step may be performed to remove and planarize an upper surface of the encapsulant 152. In some embodiments, surfaces of the underfill 150, the encapsulant 152, and the integrated circuits dies 50 are coplanar (within process variation).

As shown in FIG. 1I, a carrier substrate de-bonding is performed to detach (or “de-bond”) the carrier substrate 102 from the redistribution structure 120, e.g., the dielectric layer 124. In accordance with some embodiments, the de-bonding includes projecting a light such as a laser light or an UV light on the release layer 104 so that the release layer 104 decomposes under the heat of the light and the carrier substrate 102 can be removed. The structure is then flipped over and placed on a tape (not shown).

Then, as shown in FIG. 1J, UBMs 160 are formed for external connection to the redistribution structure 120, e.g., the metallization pattern 126. The UBMs 160 have bump portions on and extending along the major surface of the dielectric layer 124. In some embodiments, the UBMs 160 are formed of the same material as the metallization pattern 126.

Next, as shown in FIG. 1K, conductive connectors 162 are formed on the UBMs 160. The conductive connectors 162 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 162 include a conductive material such as solder, copper, aluminum, gold, nickel, silver, palladium, tin, the like, or a combination thereof. In some embodiments, the conductive connectors 162 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 162 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

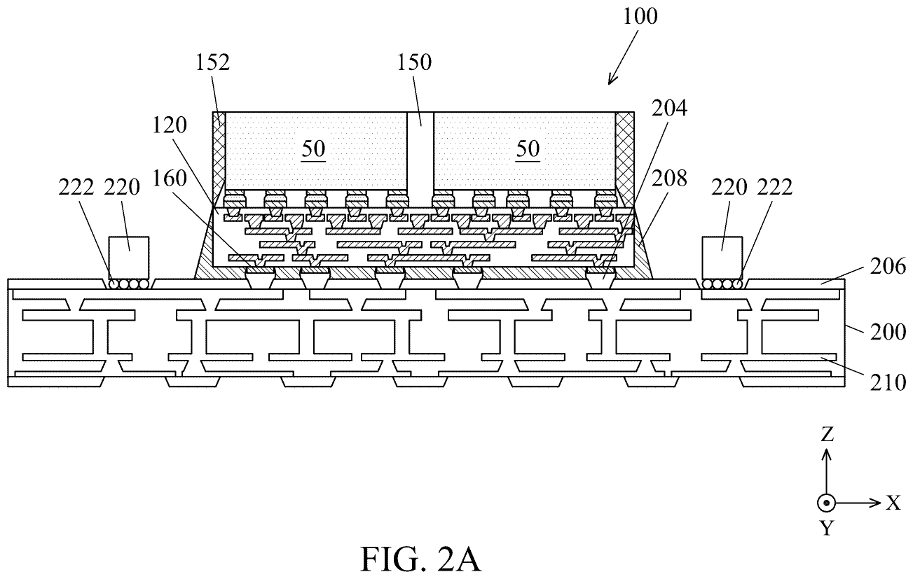

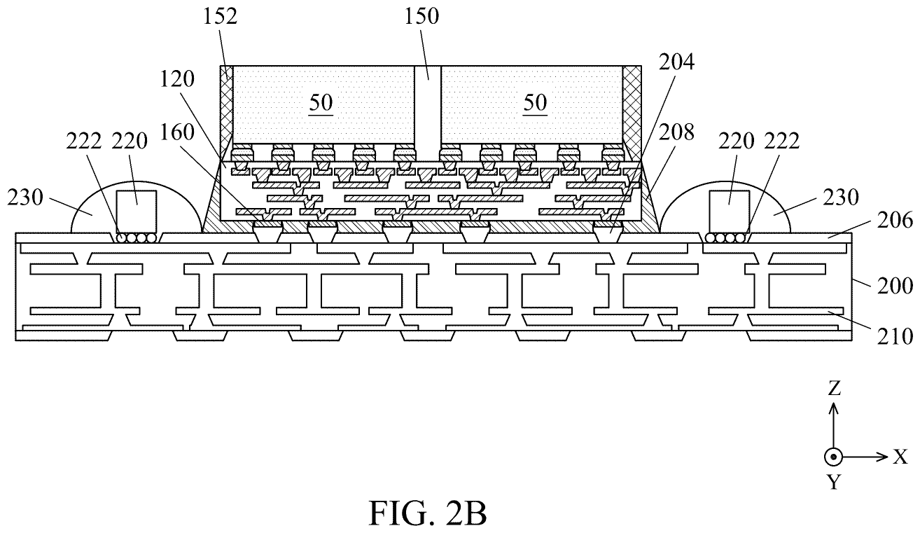

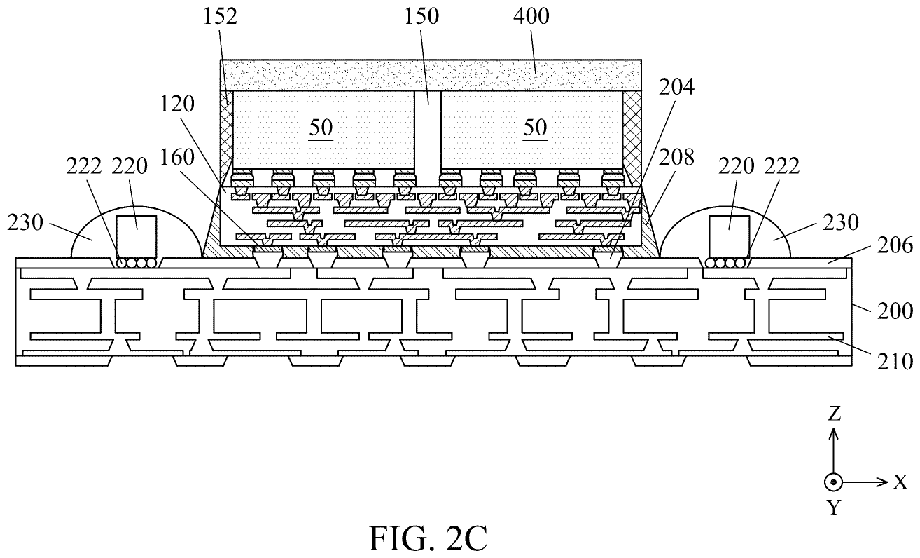

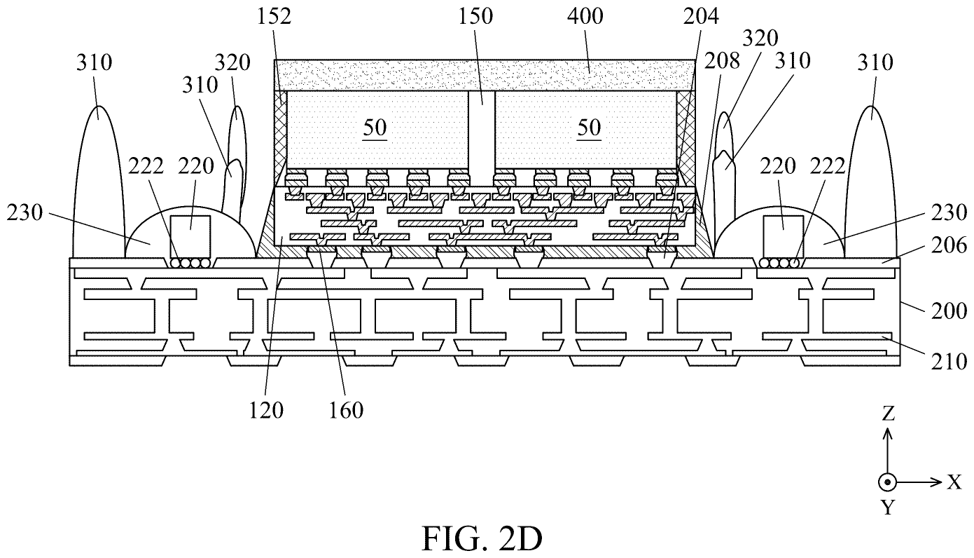

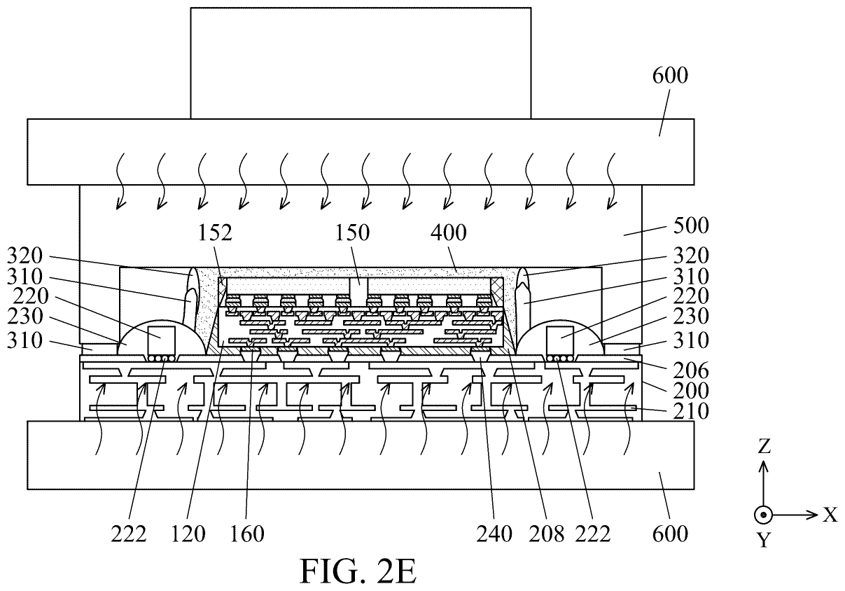

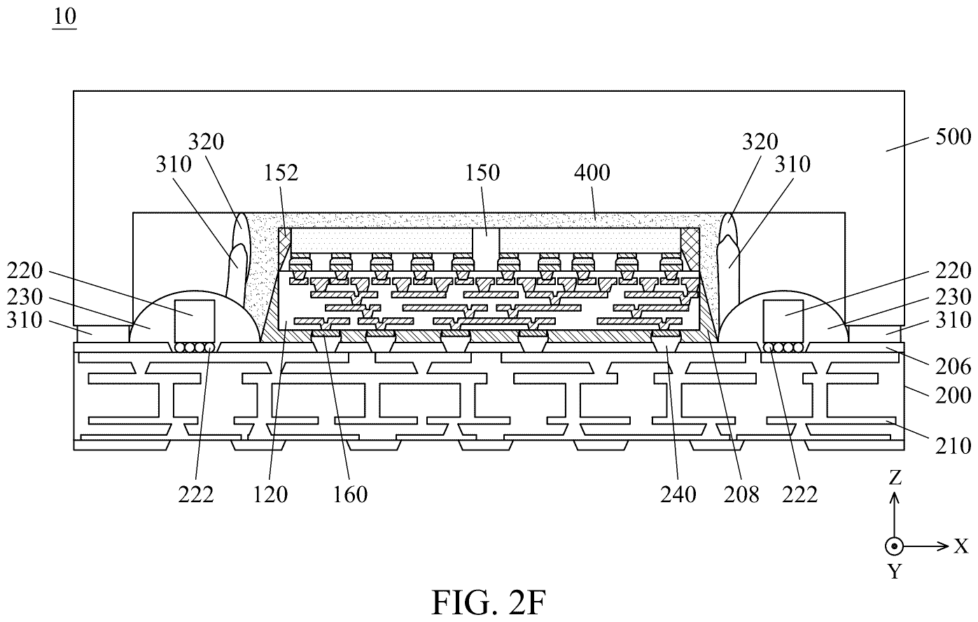

FIGS. 2A through 2F illustrate cross-sectional views of various stages of a method for fabricating a package structure 10 in accordance with some embodiments. As shown in FIG. 2A, the first package component 100 may be mounted on a second package component 200 using the conductive connectors 162. In some embodiment, the second package component 200 includes a substrate, which is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, in some embodiments, the second package component 200 is a semiconductor-on-insulator (SOI) substrate. Generally, an SOI substrate includes a layer of a semiconductor material such as epitaxial silicon, germanium, silicon germanium, SOI, SGOI, or combinations thereof. The second package component 200 is, in one alternative embodiment, based on an insulating core such as a fiberglass reinforced resin core. One example core material is fiberglass resin. Alternatives for the core material include bismaleimide-triazine (BT) resin, or alternatively, other PCB materials or films. Build up films or other laminates may be used for the second package component 200.

In some embodiments, a plurality of conductive features 210 are embedded in the second package component 200, and a plurality of bond pads 204 are formed over the second package component 200. In some embodiments, the bond pads 204 may be being physically and/or electrically coupled to the conductive features 210 in the second package component 200. In some embodiments, the conductive connectors 162 are reflowed to attach the first package component 100 to the bond pads 204. The conductive connectors 162 electrically and/or physically couple the second package component 200, including the conductive features 210 in the second package component 200, to the first package component 100. In some embodiments, a solder resist 206 is formed on the second package component 200. In some embodiments, the conductive connectors 162 are disposed in openings in the solder resist 206 to be electrically and mechanically coupled to the bond pads 204. In some embodiments, the solder resist 206 is used to protect areas of the second package component 200 from external damage.

In some embodiments, the conductive connectors 162 have an epoxy flux (not shown) formed thereon before they are reflowed with at least some of the epoxy portion of the epoxy flux remaining after the first package component 100 is attached to the second package component 200. This remaining epoxy portion may act as an underfill to reduce stress and protect the joints resulting from reflowing the conductive connectors 162. In some embodiments, an underfill 208 is formed between the first package component 100 and the second package component 200 and surrounding the conductive connectors 162. In some embodiments, the underfill 208 is formed by a capillary flow process after the second package component 200 is attached or may be formed by a suitable deposition method before the second package component 200 is attached.

In some embodiments, one or more electronic component 220 is disposed over the second package component 200. The electronic component 220 is bonded to the second package component 200 via a plurality of conductive connectors 222. In some embodiments, the electronic component 220 may be active and/or passive devices. For example, the electronic component 220 may be a wide variety of devices such as transistors, capacitors, resistors, combinations of these, and the like may be used to generate the structural and functional requirements of the design for the device stack. In some embodiments, the electronic components 220 may be formed using any suitable methods.

Next, as shown in FIG. 2B, a protective material 230 may be supplied around the electronic components 220. In some embodiments, the protective material 230 may include organic compounds or other moisture barrier materials. For example, the protective material 230 may include acrylic, epoxy, silicone-based material, or other suitable materials. Accordingly, the electronic components 220 may be encapsulated by the protective material 230, thereby reducing the risk of the failure of the electronic components 220.

Then, as shown in FIG. 2C, a thermal interface material (TIM) 400 is disposed on the first package component 100 to enhance the thermal-dissipation of the first package component 100. To be more specific, the thermal interface material 400 fully covers the integrated circuit dies 50, the underfill 150, and the encapsulant 152 to dissipate the heat generated by the integrated circuit dies 50. In some embodiments, during the formation of the thermal interface material 400, flux (not shown) may be formed on opposite sides of the thermal interface material 400 to facilitate the attachment of the thermal interface material 400 onto the first package component 100 and a lid structure (for example, the lid structure 500 shown in FIG. 2E) to be bonded subsequently.

As shown in FIG. 2D, a first adhesive wall 310 is supplied over the second package component 200, and a second adhesive wall 320 is supplied over the first adhesive wall 310. In some embodiments, a first portion of the first adhesive wall 310 is disposed on the edges of the second package component 200 for bonding the subsequent lid structure (for example, the lid structure 500 shown in FIG. 2E). For example, the first portion of the first adhesive wall 310 may be adjacent to and in contact with the protective material 230. However, the present disclosure is not limited thereto. In some embodiments, the first portion of the first adhesive wall 310 may be spaced apart from the protective material 230. In addition, a second portion of the first adhesive wall 310 and the second adhesive wall 320 are disposed over the protective material 230 for bonding the subsequent lid structure.

Then, as shown in FIG. 2E, a lid structure 500 may be bonded to the second package component 200 via the first adhesive wall 310 and the second adhesive wall 320. In some embodiments, a fixture 600 may be provided on the lid structure 500 and the second package component 200 to facilitate the bonding of the lid structure 500. With the arrangement of the first adhesive wall 310 and the second adhesive wall 320, the lid structure 500 may be bonded onto the second package component 200 more firmly.

In particular, during the formation of the package structure 10, a thermal treatment may be performed for bonding the lid structure 500. Accordingly, the thermal interface material 400 may flow outward (i.e., towards the edges of the second package component 200), and therefore voids or defects may exist in the thermal interface material 400 over the first package component 100. The second portion of the first adhesive wall 310 and the second adhesive wall 320 may also serve as a barrier for the thermal interface material 400. With the arrangement of the barrier, which includes the second portion of the first adhesive wall 310 and the second adhesive wall 320, the thermal interface material 400 may be confined within a predetermined region. As a result, the voids or defects in the thermal interface material 400 may be reduced.

As shown in FIG. 2F, the fixture 600 is removed. Accordingly, the package structure 10 is formed. It should be noted that the package structure 10 may include other portions or elements to achieve the desired functions, and these derived embodiments of the package structure 10 are also included within the scope of the present disclosure.

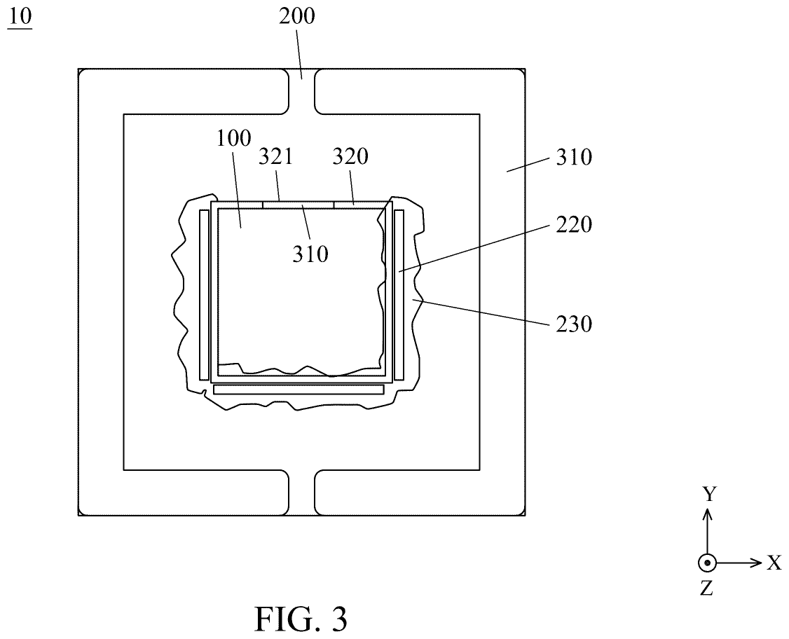

FIG. 3 illustrates a schematic top view of the package structure 10 in accordance with some embodiments. As shown in FIG. 3, the electronic components 220 are disposed around the first package component 100. In some embodiments, the electronic components 220 are disposed on three sides of the first package component 100. However, the present disclosure is not limited thereto. In some embodiments, an opening 321 is formed in the second adhesive wall 320. The opening 321 exposes the underlying first adhesive wall 310. The opening 321 may be configured to relieve the pressure of the thermal interface material 400. To be more specific, the thermal interface material 400 may flow through the opening 321 to remain flat over the first package component 100, which helps to keep the lid structure 500 in position. In some embodiments, the opening 321 is formed on the side where no electronic component 220 is disposed. However, the present disclosure is not limited thereto. In some other embodiments, multiple openings 321 may be formed at any suitable position.

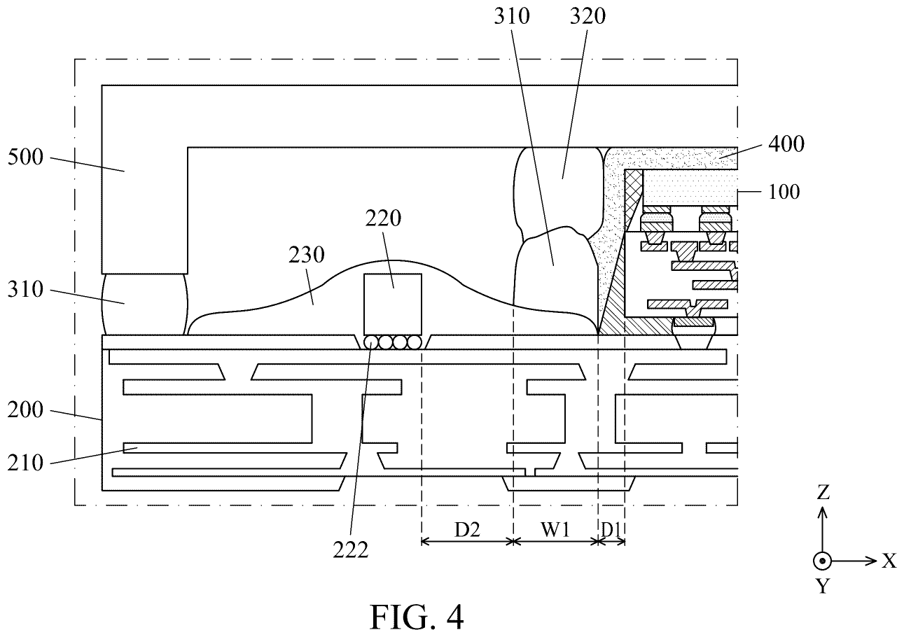

FIG. 4 illustrates a cross-sectional view of the package structure 10 in accordance with some embodiments. As shown in FIG. 4, the first adhesive wall 310 and the second adhesive wall 320 are formed over the protective material 230 and located between the electronic component 220 and the first package component 100. In some embodiments, the width W1 of the first adhesive wall 310 (or the second adhesive wall 320) may be in a range from about 1 mm to about 3 mm. In some embodiments, the distance D1 between the first package component 100 and the first adhesive wall 310 (or the second adhesive wall 320) may be less than or equal to about 2 mm. That is, the first package component 100 and the first adhesive wall 310 (or the second adhesive wall 320) may contact with each other. In some embodiments, the distance D2 between the electronic component 220 and the first adhesive wall 310 (or the second adhesive wall 320) may be less than or equal to about 2 mm. It should be noted that the distance D1 may be referred to as the shortest distance between the first package component 100 and the first adhesive wall 310 (or the second adhesive wall 320) in a horizontal direction (for example, parallel to the X direction). Similarly, the distance D2 may be referred to as the shortest distance between the electronic component 220 and the first adhesive wall 310 (or the second adhesive wall 320) in the horizontal direction (for example, parallel to the X direction).

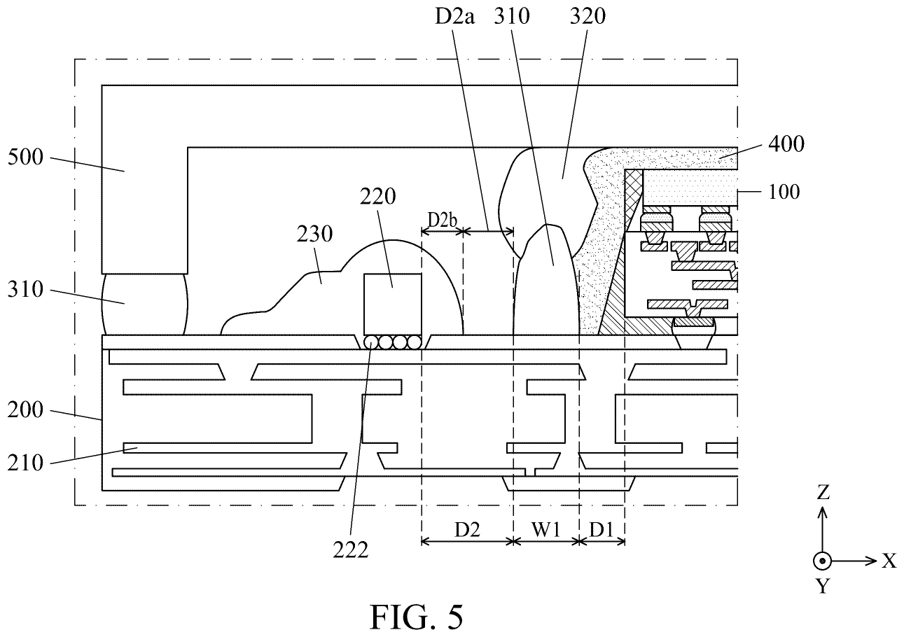

FIG. 5 illustrates a cross-sectional view of the package structure 10 in accordance with some embodiments. It should be noted that the package structure in this embodiment may include the same or similar portions or elements as those of the package structure in FIG. 4. For the sake of brevity, these portions or elements will be denoted as the same or similar numerals, and will not be discussed in detail as follows. As shown in FIG. 5, the first adhesive wall 310 and the second adhesive wall 320 are spaced apart from the protective material 230. Accordingly, the first adhesive wall 310 may be disposed over the second package component 200 without the protective material 230 formed therebetween. In some embodiments, the distance D2a between the protective material 230 and the first adhesive wall 310 (or the second adhesive wall 320) may be less than or equal to about 1 mm. It should be noted that the distance D2a may be referred to as the shortest distance between the protective material 230 and the first adhesive wall 310 (or the second adhesive wall 320) in a horizontal direction (for example, parallel to the X direction). In addition, the distance D2b may be defined as the shortest distance between the edge of the electronic component 220 and the edge of the protective material 230. Accordingly, the distance D2 may be the sum of the distances D2a and D2b. In some embodiments, the distance D2b may be shorter than the distance D2a. However, the present disclosure is not limited thereto. In some other embodiments, the distance D2b may be greater than or equal to the distance D2a.

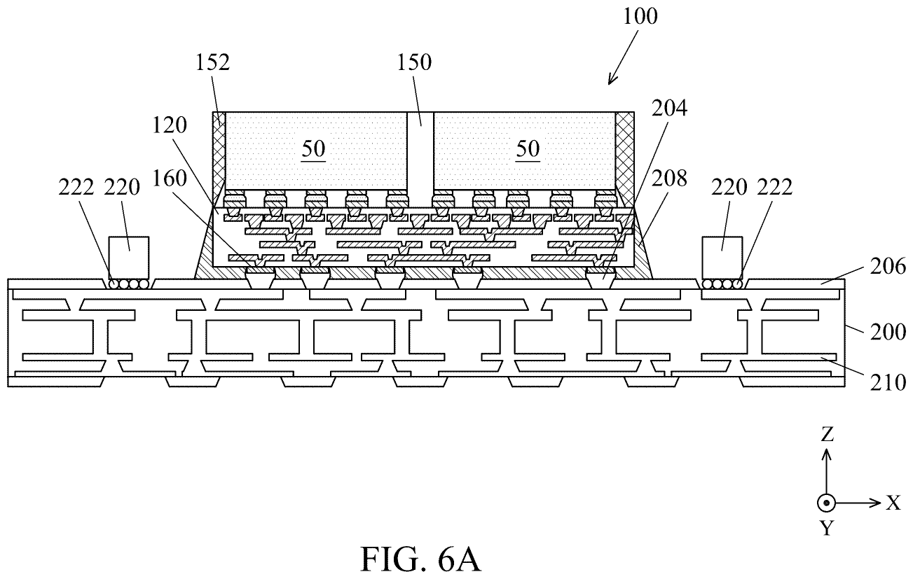

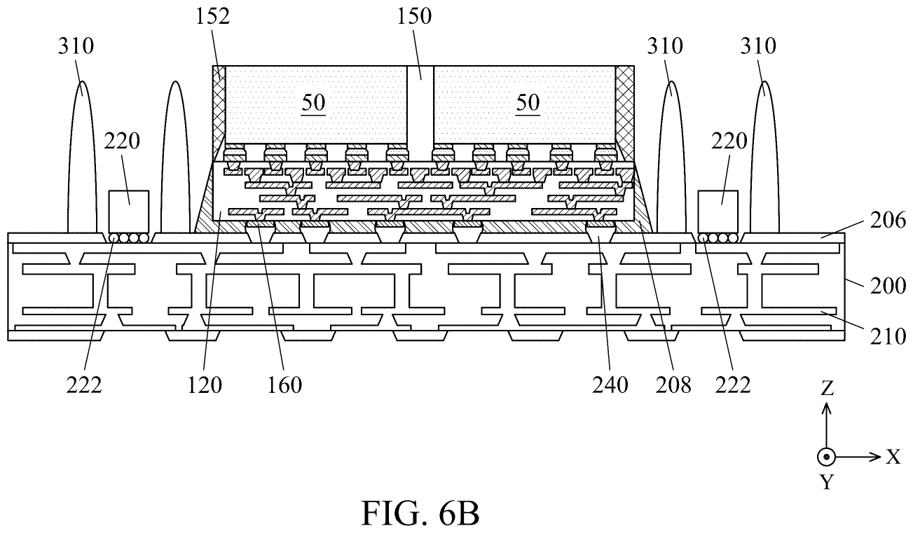

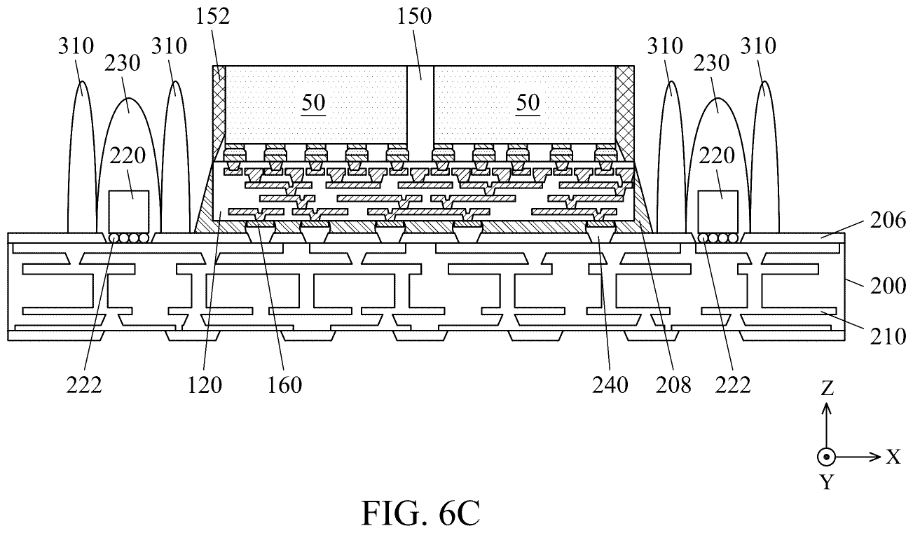

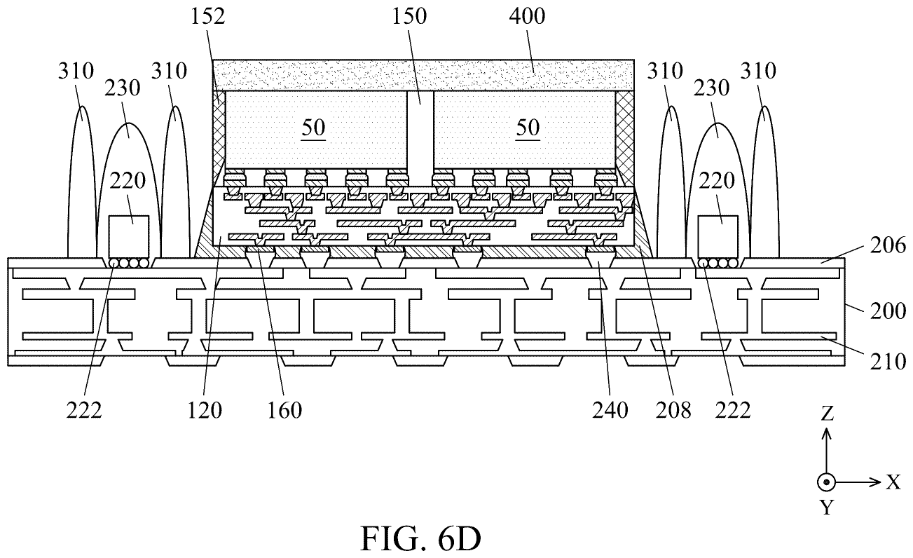

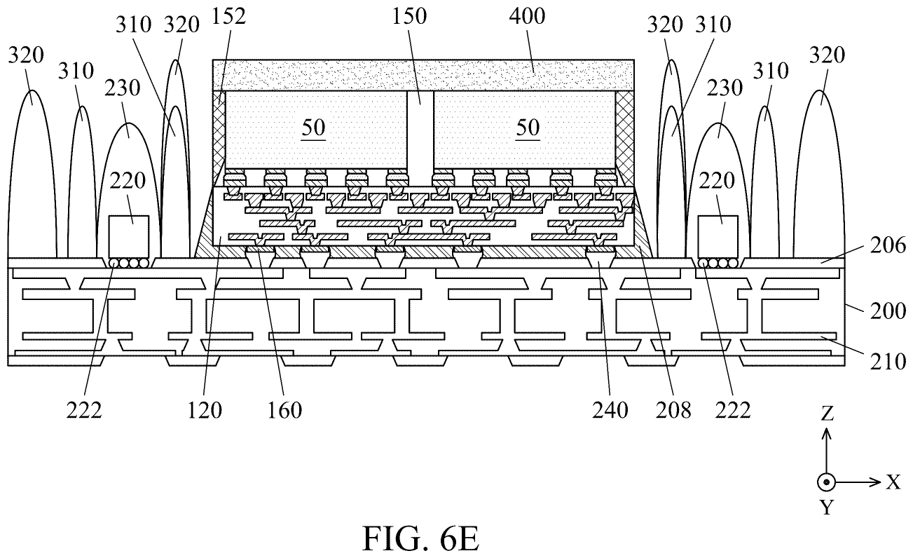

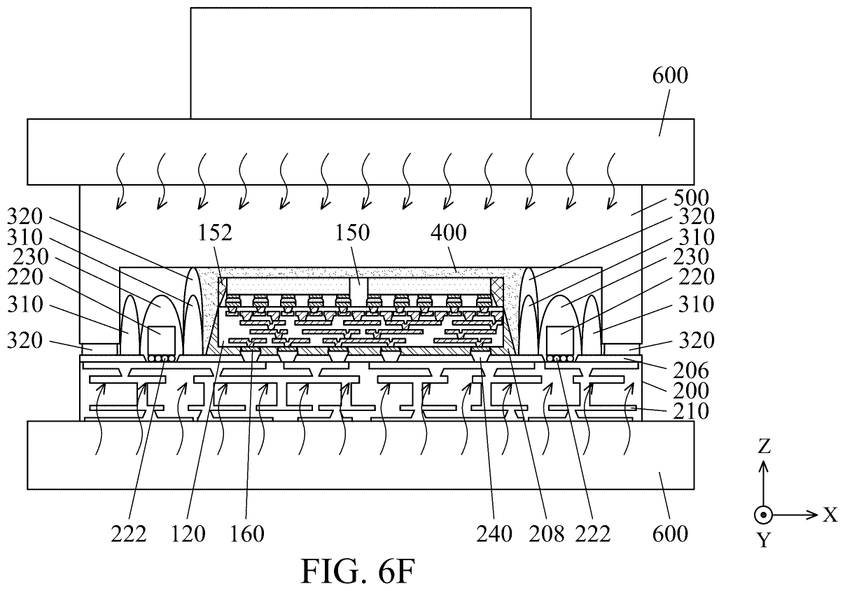

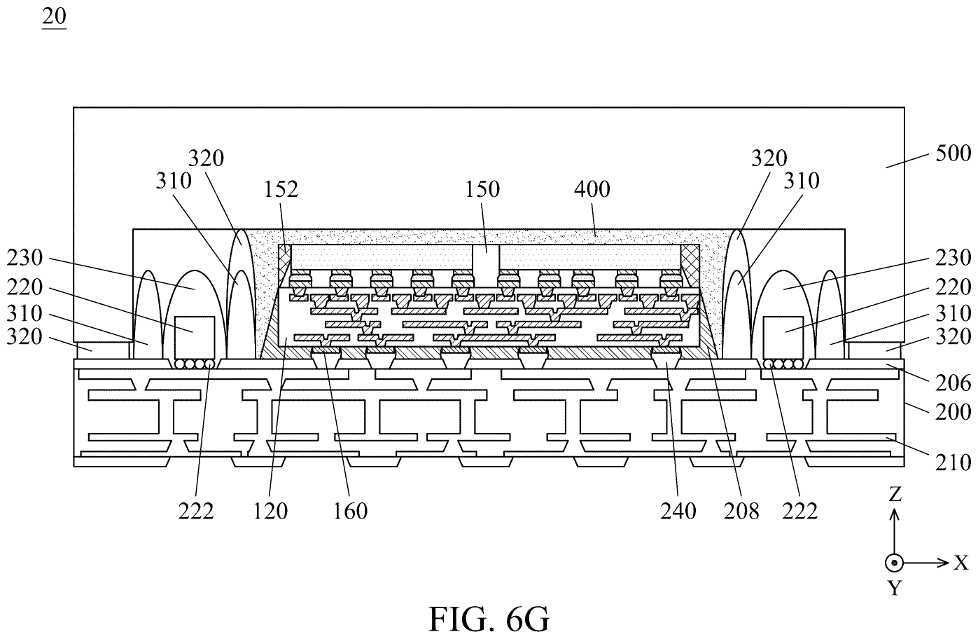

FIGS. 6A through 6G illustrate cross-sectional views of various stages of a method for fabricating the package structure 20 in accordance with some embodiments. It should be noted that the package structure in this embodiment may include the same or similar portions or elements as those of the package structure in FIGS. 2A through 2F. For the sake of brevity, these portions or elements will be denoted as the same or similar numerals, and will not be discussed in detail as follows. As shown in FIG. 6A, the first package component 100 may be mounted on a second package component 200 using the conductive connectors 162, and one or more electronic component 220 is disposed over the second package component 200. The electronic component 220 is bonded to the second package component 200 via a plurality of conductive connectors 222.

Next, as shown in FIG. 6B, a first adhesive wall 310 is supplied over the second package component 200. The first adhesive wall 310 is located on opposite sides of the electronic component 220. Then, as shown in FIG. 6C, a protective material 230 may be supplied around the electronic components 220. In some embodiments, the protective material 230 may be confined within the region defined by the first adhesive wall 310. Accordingly, the dimensions (such as the width and the height) of the protective material 230 may be controlled, thereby reducing the cost of forming the protective material 230.

Then, as shown in FIG. 6D, a thermal interface material (TIM) 400 is disposed on the first package component 100 to enhance the thermal-dissipation of the first package component 100. Next, as shown in FIG. 6E, a second adhesive wall 320 is supplied over the second package component 200 and the first adhesive wall 310. In some embodiments, a first portion of the second adhesive wall 320 is disposed on the edges of the second package component 200 for bonding the subsequent lid structure (for example, the lid structure 500 shown in FIG. 6F). For example, the first portion of the second adhesive wall 320 may be spaced apart from the protective material 230 since the protective material 230 is surrounded by the first adhesive wall 310. In addition, a second portion of the second adhesive wall 320 and the underlying first adhesive wall 310 are disposed for bonding the subsequent lid structure.

Then, as shown in FIG. 6F, a lid structure 500 may be bonded to the second package component 200 via the first adhesive wall 310 and the second adhesive wall 320. In some embodiments, a fixture 600 may be provided on the lid structure 500 and the second package component 200 to facilitate the bonding of the lid structure 500. With the arrangement of the first adhesive wall 310 and the second adhesive wall 320, the lid structure 500 may be bonded onto the second package component 200 more firmly.

In particular, during the formation of the package structure 10, a thermal treatment may be performed for bonding the lid structure 500. Accordingly, the thermal interface material 400 may flow outward (i.e., towards the edges of the second package component 200), and therefore voids or defects may exist in the thermal interface material 400 over the first package component 100. The first adhesive wall 310 and the second portion of the second adhesive wall 320 may also serve as a barrier for the thermal interface material 400. With the arrangement of the barrier, which includes the first adhesive wall 310 and the second portion of the second adhesive wall 320, the thermal interface material 400 may be confined within a predetermined region. As a result, the voids or defects in the thermal interface material 400 may be reduced.

As shown in FIG. 6G, the fixture 600 is removed. Accordingly, the package structure 20 is formed. It should be noted that the package structure 20 may include other portions or elements to achieve the desired functions, and these derived embodiments of the package structure 20 are also included within the scope of the present disclosure.

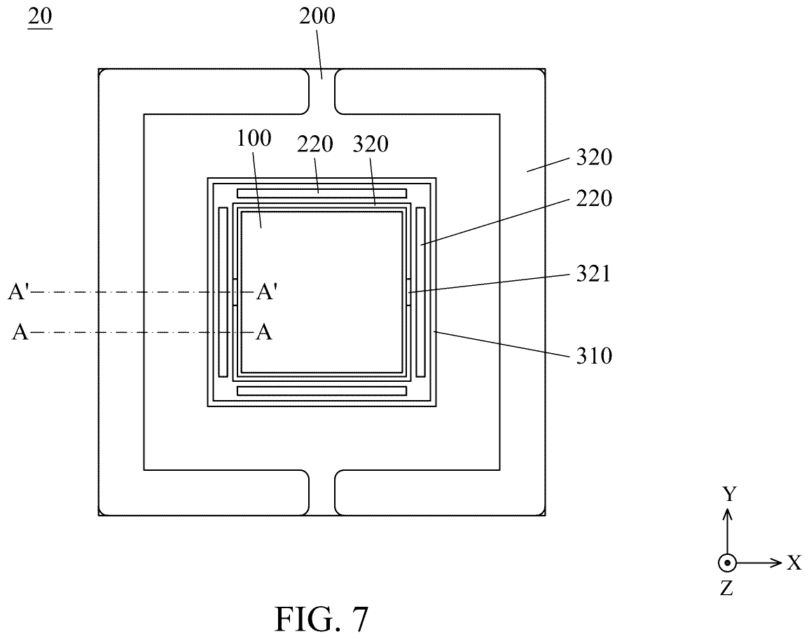

FIG. 7 illustrates a schematic top view of the package structure 20 in accordance with some embodiments. As shown in FIG. 7, the electronic components 220 are disposed around the first package component 100. In some embodiments, the electronic components 220 are disposed on each side of the first package component 100. However, the present disclosure is not limited thereto. In some embodiments, multiple openings 321 are formed in the second adhesive wall 320. The openings 321 may expose the underlying first adhesive wall 310. The openings 321 may be configured to relieve the pressure of the thermal interface material 400. To be more specific, the thermal interface material 400 may flow through the openings 321 to remain flat over the first package component 100, which helps to keep the lid structure 500 in position. It should be noted that the openings 321 may be formed at any suitable position.

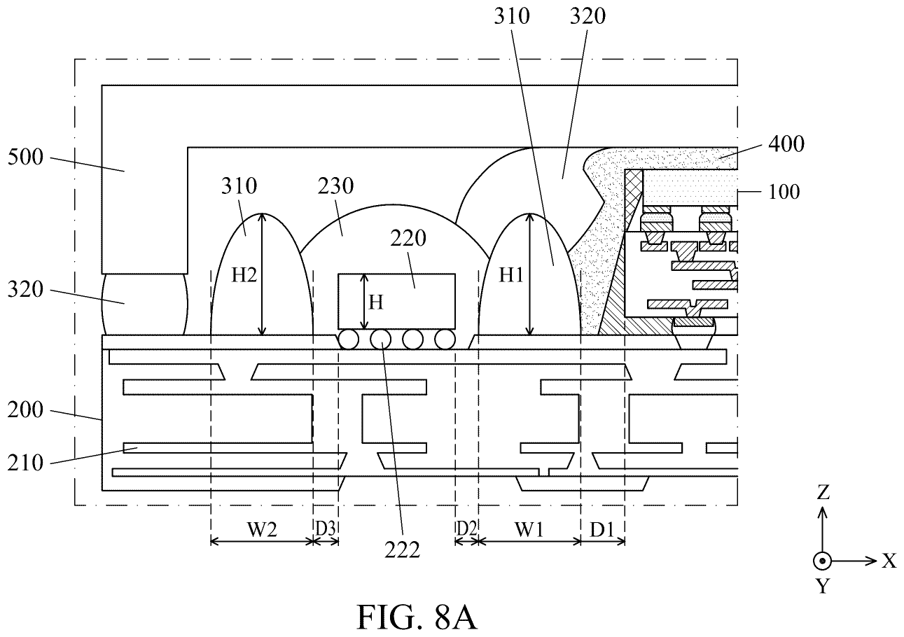

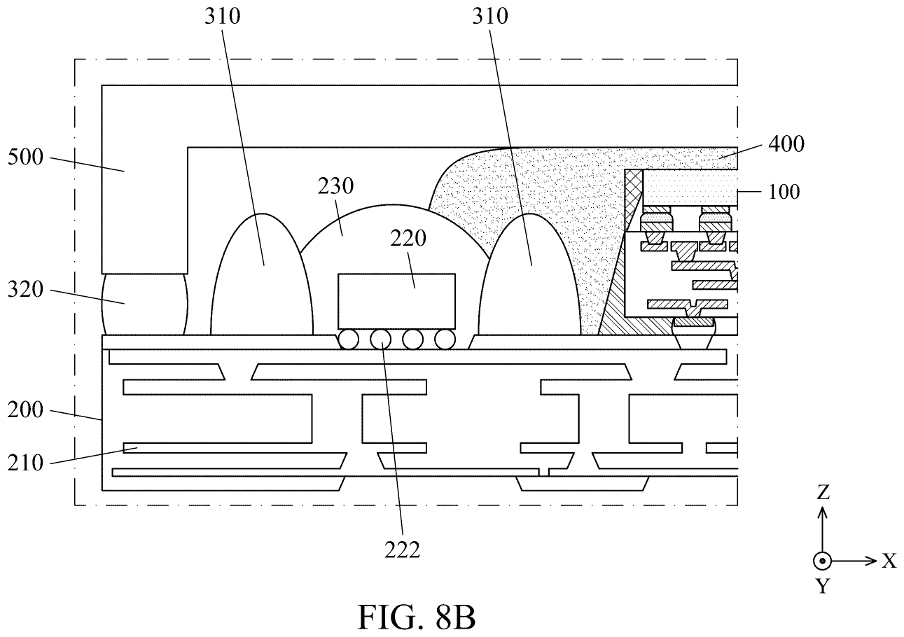

FIGS. 8A and 8B illustrate cross-sectional views of the package structure 20 in accordance with some embodiments. It should be noted that FIG. 8A may be illustrated along the line A-A in FIG. 7, and FIG. 8B may be illustrated along the line A‘-A’ in FIG. 7. However, the present disclosure is not limited thereto. As shown in FIG. 8A, the heights H1 and H2 of the first adhesive wall 310 may be greater than the height H of the electronic components 220. In some embodiments, the heights H1 and H2 of the first adhesive wall 310 may be less than or equal to about 1 mm. Accordingly, the first adhesive wall 310 may define a distribution region for the protective material 230. In some embodiments, the height H1 may be substantially equal to the height H2. However, the present disclosure is not limited thereto.

In some embodiments, the widths W1 and W2 of the first adhesive wall 310 may be in a range from about 1 mm to about 3 mm. In some embodiments, the distance D1 between the first package component 100 and the first adhesive wall 310 (or the second adhesive wall 320) may be less than or equal to about 2 mm. That is, the first package component 100 and the first adhesive wall 310 (or the second adhesive wall 320) may contact with each other. In some embodiments, the distances D2 and D3 between the electronic component 220 and the first adhesive wall 310 (or the second adhesive wall 320) may be less than or equal to about 2 mm. It should be noted that the distance D1 may be referred to as the shortest distance between the first package component 100 and the first adhesive wall 310 (or the second adhesive wall 320) in the horizontal direction (for example, parallel to the X direction). Similarly, the distances D2 and D3 may be referred to as the shortest distance between the electronic component 220 and the first adhesive wall 310 (or the second adhesive wall 320) in the horizontal direction (for example, parallel to the X direction).

As shown in FIG. 8B, the thermal interface material 400 may flow through the openings 321 and therefore over the first adhesive wall 310. In some embodiments, the thermal interface material 400 may be in contact with the protective material 230. However, the present disclosure is not limited thereto. Since the electronic component 220 is encapsulated by the protective material 230, the electronic component 220 is protected from the thermal interface material 400. As a result, the electronic component 220 would not be damaged by the thermal interface material 400.

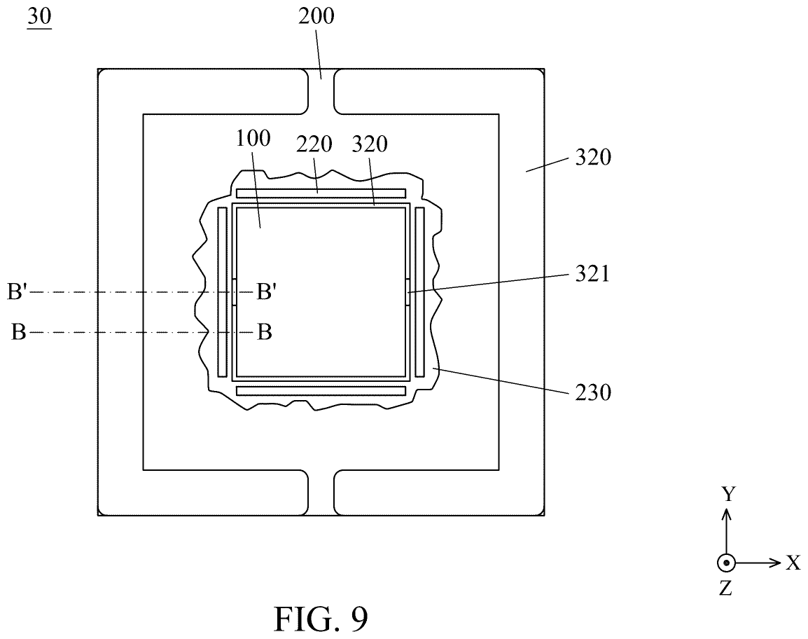

FIG. 9 illustrates a schematic top view of the package structure 30 in accordance with some embodiments. It should be noted that the package structure 30 in this embodiment may include the same or similar portions or elements as those of the package structure 20 in FIG. 7. For the sake of brevity, these portions or elements will be denoted as the same or similar numerals, and will not be discussed in detail as follows. As shown in FIG. 9, the portion of the first adhesive wall 310 that is closer to the edges of the second package component 200 is omitted. As a result, the process for fabricating the package structure 30 is simplified.

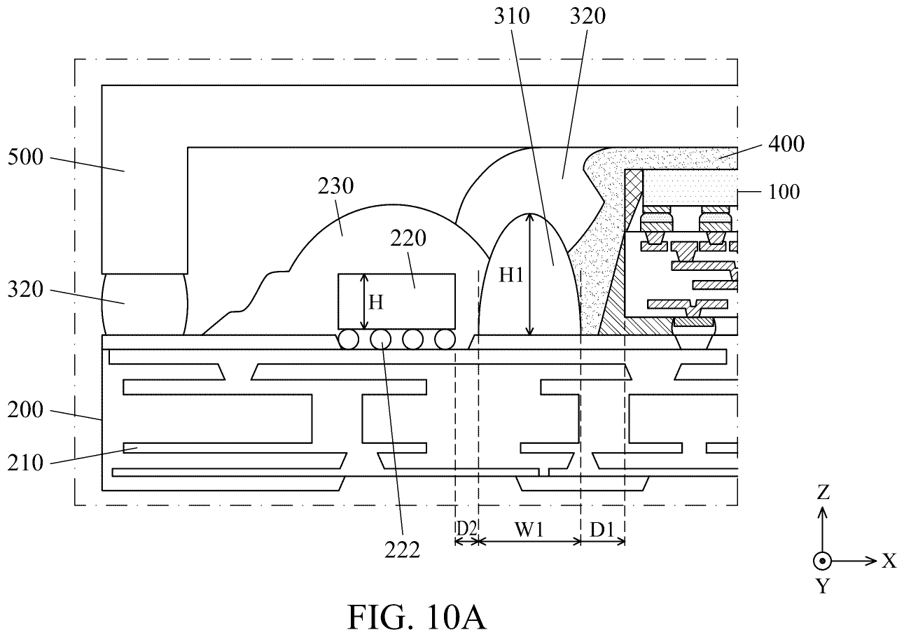

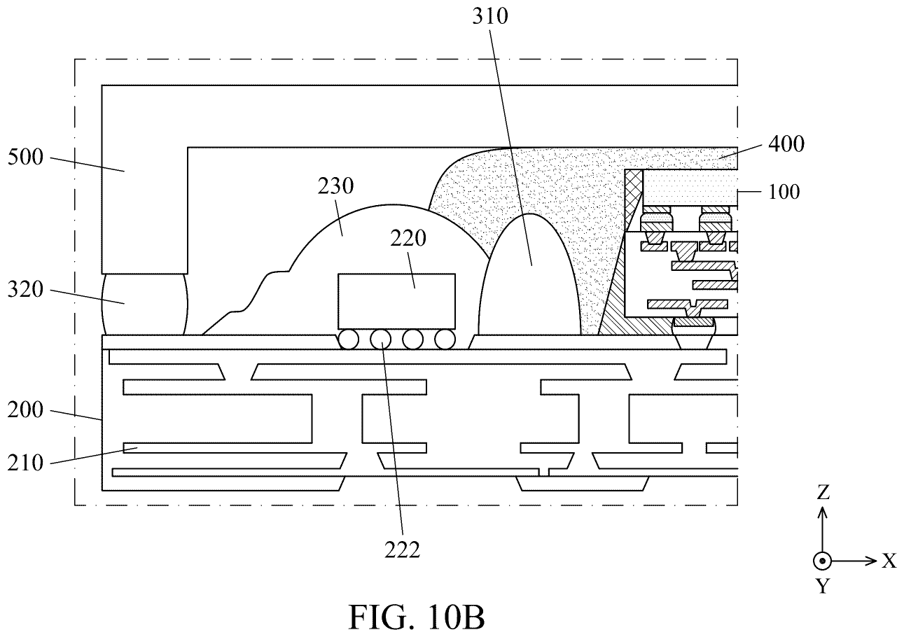

FIGS. 10A and 10B illustrate cross-sectional views of the package structure 30 in accordance with some embodiments. It should be noted that FIG. 10A may be illustrated along the line B-B in FIG. 9, and FIG. 10B may be illustrated along the line B‘-B’ in FIG. 9. As shown in FIG. 10A, the height H1 of the first adhesive wall 310 may be greater than the height H of the electronic components 220. In some embodiments, the height H1 of the first adhesive wall 310 may be less than or equal to about 1 mm. However, the present disclosure is not limited thereto.

In some embodiments, the width W1 of the first adhesive wall 310 may be in a range from about 1 mm to about 3 mm. In some embodiments, the distance D1 between the first package component 100 and the first adhesive wall 310 (or the second adhesive wall 320) may be less than or equal to about 2 mm. That is, the first package component 100 and the first adhesive wall 310 (or the second adhesive wall 320) may contact with each other. In some embodiments, the distance D2 between the electronic component 220 and the first adhesive wall 310 (or the second adhesive wall 320) may be less than or equal to about 2 mm. It should be noted that the distance D1 may be referred to as the shortest distance between the first package component 100 and the first adhesive wall 310 (or the second adhesive wall 320) in the horizontal direction (for example, parallel to the X direction). Similarly, the distance D2 may be referred to as the shortest distance between the electronic component 220 and the first adhesive wall 310 (or the second adhesive wall 320) in the horizontal direction (for example, parallel to the X direction).

As shown in FIG. 10B, the thermal interface material 400 may flow through the openings 321 and therefore over the first adhesive wall 310. In some embodiments, the thermal interface material 400 may be in contact with the protective material 230. However, the present disclosure is not limited thereto. Since the electronic component 220 is encapsulated by the protective material 230, the electronic component 220 is protected from the thermal interface material 400. As a result, the electronic component 220 would not be damaged by the thermal interface material 400.

Embodiments of package structures and method for fabricating the same are provided. The package structure includes adhesive walls as a barrier to confine the thermal interface material within a predetermined region. As a result, the voids or defects in the thermal interface material may be reduced. In addition, at least one opening is formed in the adhesive walls to relieve the pressure of the thermal interface material. To be more specific, the thermal interface material may flow through the openings to remain flat over the first package component, which helps to keep the lid structure in position. Moreover, the protective material may be confined within the region defined by the first adhesive wall. Accordingly, the dimensions (such as the width and the height) of the protective material may be controlled, thereby reducing the cost of forming the protective material.

In some embodiments, a package structure is provided. The package structure includes a first package component and a second package component bonded to the first package. The package structure includes an electronic component disposed on the second package component. The package structure includes a thermal interface material over the first package component. The package structure includes a first adhesive wall located between the first package component and the electronic component. The package structure also includes a lid structure bonded to the second package component.

In some embodiments, a method for fabricating a package structure is provided. The method includes bonding a first package component to a second package component. The method includes mounting an electronic component onto the second package component. The method includes forming a first adhesive wall over the second package component. The first adhesive wall is located between the first package component and the electronic component. The method includes forming a second adhesive wall over the first adhesive wall. The method includes forming a thermal interface material over the first package component and covering sidewalls of the first adhesive wall and the second adhesive wall. The method also includes bonding a lid structure over the second package component.

In some embodiments, a method for fabricating a package structure is provided. The method includes disposing a first package component over a second package component. The method includes mounting an electronic component onto the second package component. The method includes forming a protective material covering the electronic component. The method includes forming a first adhesive wall over the second package component. The method includes forming a second adhesive wall over the first adhesive wall. The method includes forming a thermal interface material over the first package component. The portion of the thermal interface material is sandwiched between the first package component and the second adhesive wall. The method also includes bonding a lid structure over the second package component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first package component;
a second package component bonded to the first package;
an electronic component disposed on the second package component;
a thermal interface material over the first package component;
a first adhesive wall located between the first package component and the electronic component; and
a lid structure bonded to the second package component.

2. The package structure as claimed in claim 1, further comprising a second adhesive wall over the first adhesive wall, wherein the thermal interface material contacts the first adhesive wall or the second adhesive wall.

3. The package structure as claimed in claim 2, wherein an opening is formed in the second adhesive wall, and the thermal interface material passes through the opening of the second adhesive wall.

4. The package structure as claimed in claim 2, wherein the first adhesive wall or the second adhesive wall is disposed on edges of the second package component, and the lid structure is bonded to the second package component via the first adhesive wall or the second adhesive wall.

5. The package structure as claimed in claim 1, further comprising a protective material covering the electronic component, wherein the first adhesive wall is in contact with the protective material.

6. The package structure as claimed in claim 5, wherein the first adhesive wall is spaced apart from the protective material.

7. The package structure as claimed in claim 1, wherein a width of the first adhesive wall is from about 1 mm to about 3 mm.

8. A method for fabricating a package structure, comprising:
bonding a first package component to a second package component;
mounting an electronic component onto the second package component;
forming a first adhesive wall over the second package component, wherein the first adhesive wall is located between the first package component and the electronic component;
forming a second adhesive wall over the first adhesive wall;
forming a thermal interface material over the first package component and covering sidewalls of the first adhesive wall and the second adhesive wall; and
bonding a lid structure over the second package component.

9. The method as claimed in claim 8, further comprising:
forming a protective material over the electronic component, wherein the first adhesive wall is formed on the protective material.

10. The method as claimed in claim 9, wherein the electronic component is spaced apart from the first adhesive wall via the protective material.

11. The method as claimed in claim 9, wherein the first adhesive wall is spaced apart from the protective material.

12. The method as claimed in claim 8, wherein during bonding the lid structure over the second package component, the thermal interface material flows away from the first package component and in contact with the first adhesive wall or the second adhesive wall.

13. The method as claimed in claim 8, wherein forming the second adhesive wall further comprises forming an opening to expose the underlying first adhesive wall.

14. The method as claimed in claim 13, further comprising:
performing a thermal treatment while bonding the lid structure over the second package component, wherein the thermal interface material passes through the opening during the thermal treatment.

15. A method for fabricating a package structure, comprising:
disposing a first package component over a second package component;
mounting an electronic component onto the second package component;
forming a protective material covering the electronic component;
forming a first adhesive wall over the second package component;
forming a second adhesive wall over the first adhesive wall;
forming a thermal interface material over the first package component, wherein a portion of the thermal interface material is sandwiched between the first package component and the second adhesive wall; and
bonding a lid structure over the second package component.

16. The method as claimed in claim 15, wherein the first adhesive wall is formed higher than the electronic component.

17. The method as claimed in claim 15, wherein the second adhesive wall is formed over edges of the second package component, and the lid structure is bonded over the second package component via the second adhesive wall.

18. The method as claimed in claim 15, wherein the first adhesive wall is formed on opposite sides of the electronic component, and the protective material is surrounded by and in contact with the first adhesive wall.

19. The method as claimed in claim 15, wherein forming the second adhesive wall further comprises forming an opening to expose the underlying first adhesive wall.

20. The method as claimed in claim 19, further comprising:
performing a thermal treatment while bonding the lid structure over the second package component, wherein the thermal interface material flows over the first adhesive wall via the opening during the thermal treatment.
